(19) United States
(12) Patent Application Publication
(10) Pub. No.: US 2005/0145931 A1
(43) Pub. Date: Jul. 7, 2005

(54) Semiconductor device and fabricating method thereof

(75) Inventor: Joo Hyun Lee, Icheon (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor, Inc.

(21) Appl. No.: 11/022,832

(22) Filed: Dec. 28, 2004

(30) Foreign Application Priority Data
Dec. 30, 2003 (KR) P 2003-0100388

(51) Int. Cl. H01L 29/76

(52) U.S. Cl. 257/327

(57) ABSTRACT

The present invention provides a semiconductor device and fabricating method thereof, by which dislocation is previously prevented from occurring between a spacer and a substrate. The present invention includes forming a gate having a gate insulating layer underneath on a semiconductor substrate, forming a pair of lightly doped regions in the substrate to be aligned with the gate, forming at least two insulating layers on the substrate including the gate, forming a spacer on a sidewall of the gate by patterning the insulating layer, removing an edge portion of a lower one of the at least two insulating layers to a prescribed width, forming a pair of heavily doped regions in the substrate to be aligned with the spacer, and forming a silicide layer on a surface of the gate electrode and exposed surfaces of the lightly and heavily doped regions.

This application claims the benefit of the Korean Application No. P2003-0100388 filed on Dec. 30, 2003, which is hereby incorporated by reference.

### BACKGROUND OF THE INVENTION

1. Field of the Invention

The present invention relates to a semiconductor device and fabricating method thereof, by which dislocation is previously prevented from occurring between a spacer and substrate.

2. Discussion of the Related Art

Lately, a semiconductor device fabrication technology is developed into a sub-micron unit to provide the high degree of integration and excellent drivability of circuit. The characteristics of the semiconductor device can be balanced only if the dimensional reduction of the semiconductor is horizontally and vertically made. If such a requirement for the dimensional reduction of the semiconductor device fails to be met, a channel length between source and drain is shortened to result in unfavorable variations of the semiconductor device characteristics such as the short channel effect (SCE).

To overcome the short channel effect, a horizontal reduction in a gate electrode width and the like needs to be simultaneously made together with a vertical reduction in gate insulating layer thickness, source/drain junction depth, and the like. Moreover, according to the horizontal and vertical reductions, a voltage of a power source is lowered, a doping density of a semiconductor substrate is raised, and more specifically, a doping profile in a channel area should be efficiently controlled.

Yet, since the operational power requested by an electronic product is still high despite the dimensional reduction of the semiconductor device, electrons injected from a source of an NMOS transistor are severely accelerated in a potential gradient state of a drain to make the NMOS transistor vulnerable to hot carrier generation for example. To overcome such a problem, an LDD (lightly doped drain) structure improving the NMOS transistor vulnerable to hot carriers has been proposed. In a transistor of the LDD structure, a lightly doped region (n−) is inserted between a channel and a heavily doped drain/source (n+) to buffer a high drain voltage in the vicinity of the drain junction. Hence, the lightly doped region interrupts the abrupt potential variation to suppress the hot carrier generation. Since many efforts have been made to development of a highly increased degree of semiconductor device integration, various methods for fabrication LDD MOSFET have been proposed. One of the various methods is an LDD fabrication method using a spacer provided to a sidewall of a gate electrode, which is currently and mostly adopted as a method for mass production.

FIGS. 1A to 1E are cross-sectional diagrams for explaining a method of fabricating a semiconductor device according to a related art.

Referring to FIG. 1A, a device isolation layer 102 is formed in a field area of a semiconductor substrate 101 by STI (shallow trench isolation) for electric insulation between active areas of the semiconductor substrate 101 that is a p type as a first conductive type for example.

A gate insulating layer 103 is then formed on the active areas. In doing so, an oxide layer is grown by thermal oxidation.

A polysilicon layer for a gate electrode is deposited on the gate insulating layer 103 by low pressure CVD (chemical vapor deposition) and is then patterned to form a pattern of a gate electrode 104 by photolithography.

LDD ion implantation is carried out on the substrate 101 to form lightly doped regions (n−) in the active area of the semiconductor substrate 101 using a second conductive type dopant such as phosphor (P). In doing so, the gate electrode. 104 is doped with the second conductive type dopant.

Referring to FIG. 1B, prescribed thermal oxidation is carried out on the substrate to heal the gate insulating layer damaged by dry etch performed for forming the gate electrode 104.

Subsequently, an oxide layer 105 for forming a spacer 107 in FIG. 1D is formed 200 Å thick over the substrate 101 including the gate electrode 104 and the gate insulating layer 103. In doing so, the oxide layer 105 is deposited by O₃-TEOS (tetraethylortho silicate) CVD or plasma CVD.

And, a nitride layer 106 for forming the spacer 107 in FIG. 1D is deposited 800-1,000 Å thick on the oxide layer 105 by LPCVD.

Referring to FIG. 1C, the nitride layer 106 is etched back by RIE (reactive ion etch) until the oxide layer 105 on the gate electrode 104 and the active area is exposed. Hence, the nitride layer 106 remains over a sidewall of the gate electrode 104.

Referring to FIG. 1D, the oxide layer 105 is etched by dry etch until the gate electrode 104 and the semiconductor substrate 101 corresponding to a source/drain area are exposed. Hence, the oxide layer 105 remains on the sidewall of the gate electrode 104 covered with the nitride layer 106, whereby a spacer 107 consisting of the nitride layer 106 and the oxide layer 105 is completed. Alternatively, the spacer 107 can be formed as a triple layer consisting of a first oxide layer, a nitride layer, and a second oxide layer.

Referring to FIG. 1E, source/drain ion implantation is carried out on the substrate 101 to form heavily doped regions (n+) in the active area using the second conductive type dopant such as phosphor (P). In doing so, the gate electrode 104 is doped with the second conductive type dopant as well. Hence, LDD source and drain (not shown in the drawing) are formed in the active area of the semiconductor substrate 101 to be aligned with the gate electrode 104.

However, in the related art method, when the source/drain ion implantation is carried out on the substrate after completion of the spacer, the physical impact of the implanted ions cause damage to the surface and inside of the substrate in the vicinity of the spacer. Specifically, in case of using a heavy dopant such as As, the substrate damage is worsened. Besides, other damages caused by the device isolation process, the etch process for the spacer, and the like are accumulated in the semiconductor substrate. In aspect of materials science, the damages mean point defect, line defect, and the like in atomic arrangement.

Meanwhile, annealing is carried out on the defective substrate to activate the dopant, which re-crystallize the surface and inside of the substrate as well. During the recrystallization, dislocation attributed to the damage of the substrate, i.e., point defect or line defect, takes place. Specifically, stress is concentrated on an interface between the spacer and the substrate to worsen the dislocation.

As the location is concentrated on interface between the spacer and the substrate, electrical characteristics of the semiconductor device are degraded as well as leakage current may be brought about. Moreover, according to the microscopically lowered design rule of the semiconductor device, the dislocation lowers reliability of the semiconductor device.

To overcome the problems raised by the dislocation, in the related art method, annealing is carried out on the substrate after completion of each of the device isolation layer, the spacer, and the like to minimize the substrate defects.

However, such a solution makes the fabrication process more complicated and becomes an obstacle in implementing a microscopic device.

### SUMMARY OF THE INVENTION

Accordingly, the present invention is directed to a semiconductor device and fabricating method thereof that substantially obviates one or more problems due to limitations and disadvantages of the related art.

An object of the present invention is to provide a semiconductor device and fabricating method thereof, by. which dislocation is previously prevented from occurring between a spacer and substrate in fabricating a transistor.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method of fabricating a semiconductor device according to the present invention includes the steps of forming a gate having a gate insulating layer underneath on a semiconductor substrate, forming a pair of lightly doped regions in the substrate to be aligned with the gate, forming at least two insulating layers on the substrate including the gate, forming a spacer on a sidewall of the gate by patterning the insulating layer, removing an edge portion of a lower one of the at least two insulating layers to a prescribed width, forming a pair of heavily doped regions in the substrate to be aligned with the spacer, and forming a silicide layer on a surface of the gate electrode and exposed surfaces of the lightly and heavily doped regions.

Preferably, the silicide layer fills up the removed portion.

Preferably, either a double layer of oxide/nitride or oxynitride/nitride or a triple layer of oxide/nitride/oxide is used as the at least two insulating layers.

Preferably, the prescribed width is 30˜100 Å.

Preferably, the edge portion is removed by isotropic wet etch.

Preferably, 0.4-0.5 wt % diluted HF is used as an etchant for the isotropic etch.

In another aspect of the present invention, a semiconductor device includes a gate having a gate insulating layer underneath on a semiconductor substrate, a pair of lightly doped regions in the substrate to be aligned with the gate, a spacer on a sidewall of the gate configured with at least two insulating layers wherein an edge portion of a lower one of the at least two insulating layers is removed to a prescribed width, a pair of heavily doped regions in the substrate to be aligned with the spacer, and a silicide layer on a surface of the gate electrode and exposed surfaces of the lightly and heavily doped regions.

Preferably, the silicide layer fills up the removed portion.

Preferably, the prescribed width is 30˜100 Å.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1E are cross-sectional diagrams for explaining a method of fabricating a semiconductor device according to a related art;

FIG. 2 is a cross-sectional diagram of a semiconductor device according to the present invention; and

FIGS. 3A to 3E are cross-sectional diagrams for explaining a method of fabricating a semiconductor device according to the present invention.

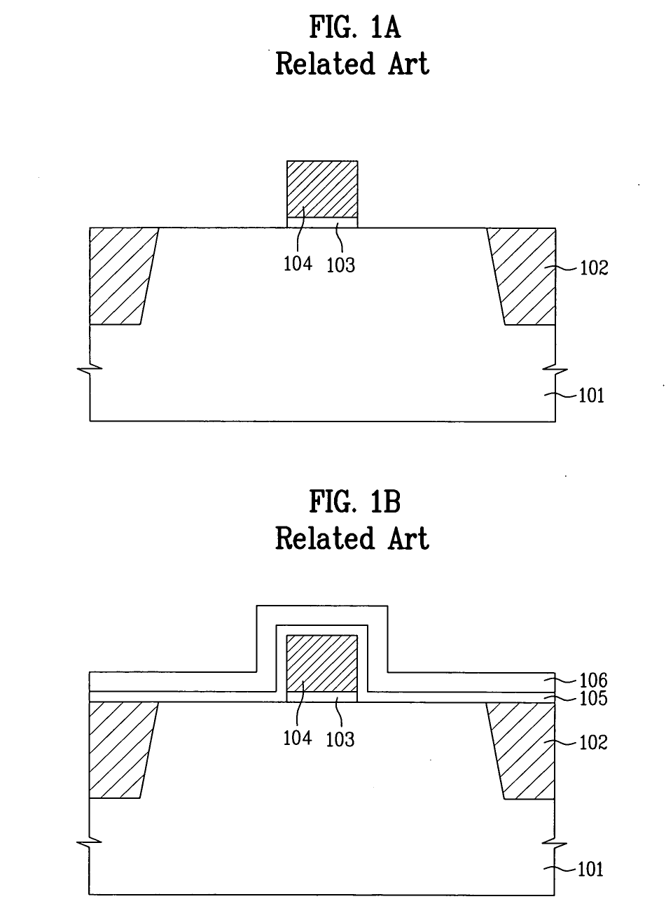

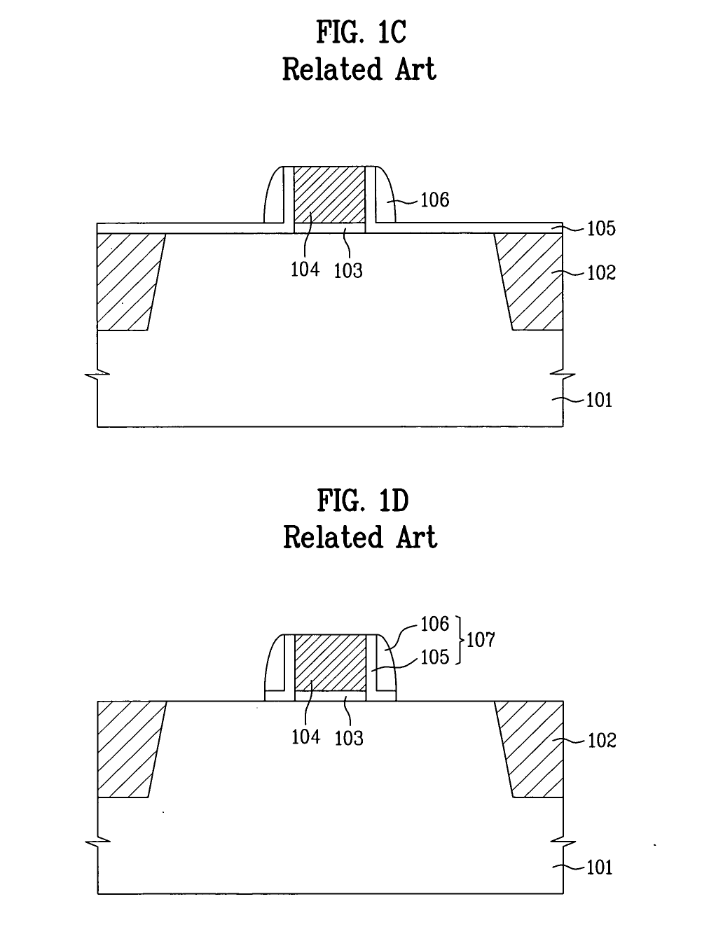

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

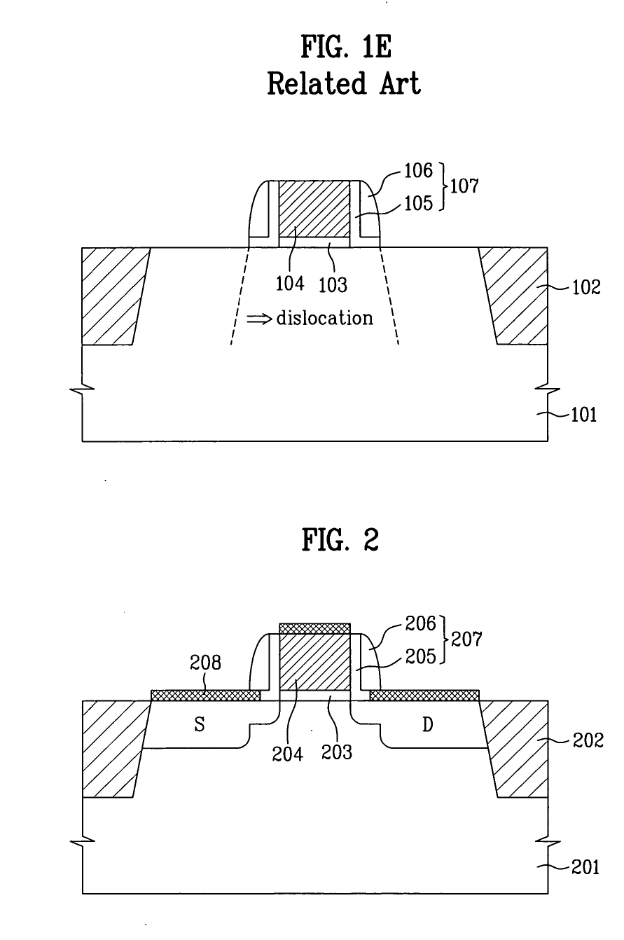

FIG. 2 is a cross-sectional diagram of a semiconductor device according to the present invention.

Referring to FIG. 2, a device isolation layer 202 is formed on a field area of a semiconductor substrate 201 to define an active area of the semiconductor substrate 201.

A gate insulating layer 203 and a gate electrode 204 are sequentially stacked on a prescribed area of the active area of the semiconductor substrate 201.

A spacer 207 formed of an insulating layer is formed on a sidewall of the gate electrode 204. The spacer 207 is configured with a double layer including an oxide layer 205 and a nitride layer 206 or a triple layer including an oxide layer, a nitride layer, and an oxide layer. An edge of the lower insulating layer 205 contacting with the substrate 201 is removed to a prescribed width.

A salicide layer 208 is provided to a surface of the gate electrode 204 and a surface of the semiconductor substrate 201 in the vicinity of a lateral side of the lower insulating layer 205 of the spacer 207. Specifically, the salicide layer 208 provided to the surface of the semiconductor substrate 201 fills up the removed portion of the lower insulating layer 205 under the upper insulating layer 206.

Thus, since the lower insulating layer 205 configuring the spacer 205 is removed to the prescribed width, it is able to prevent a stress being concentrated on the edge portion of the spacer 207 on recrystallizing the semiconductor substrate 301 by subsequent annealing and the like.

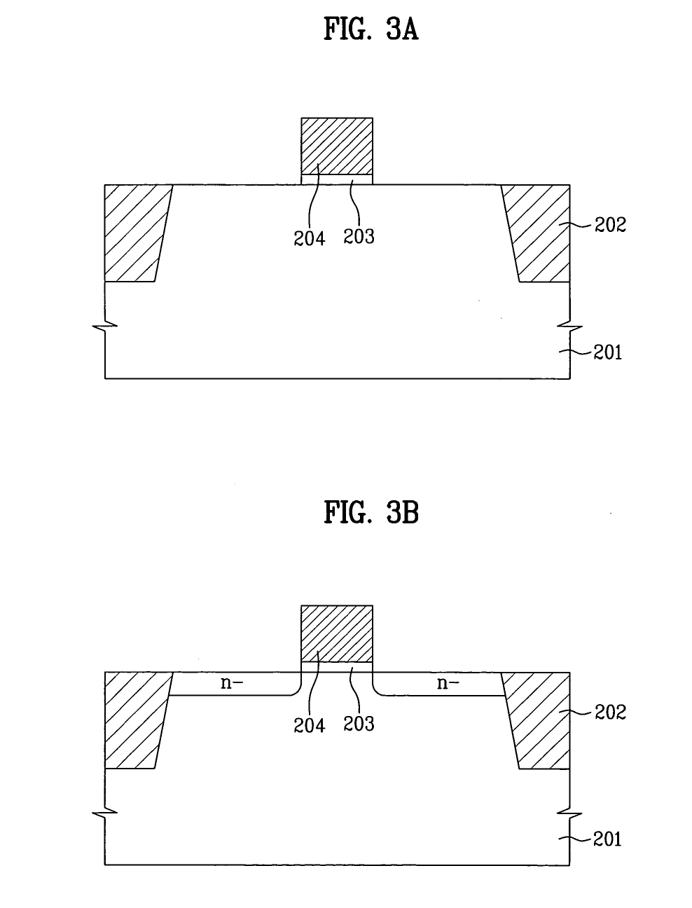

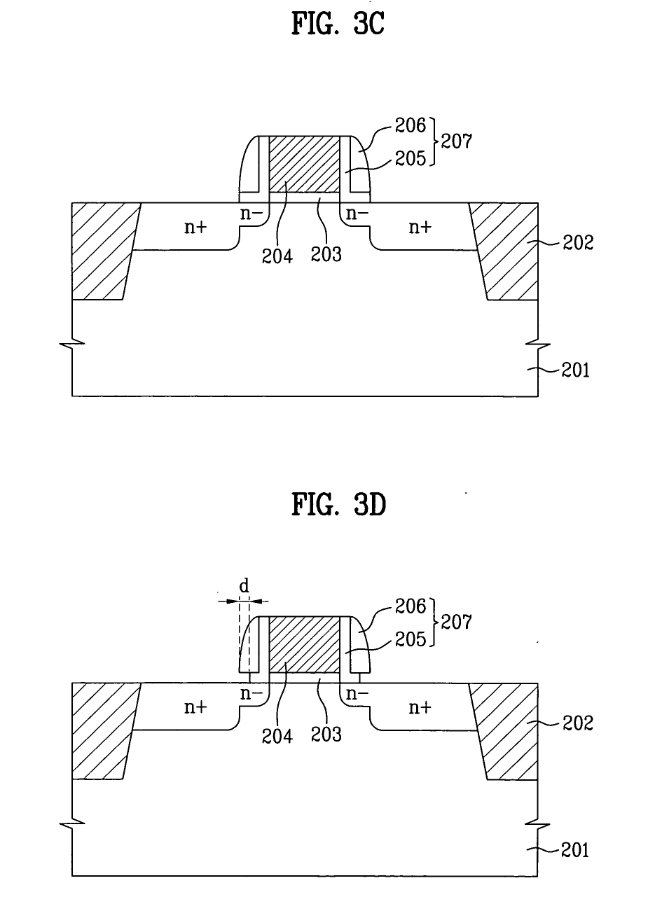

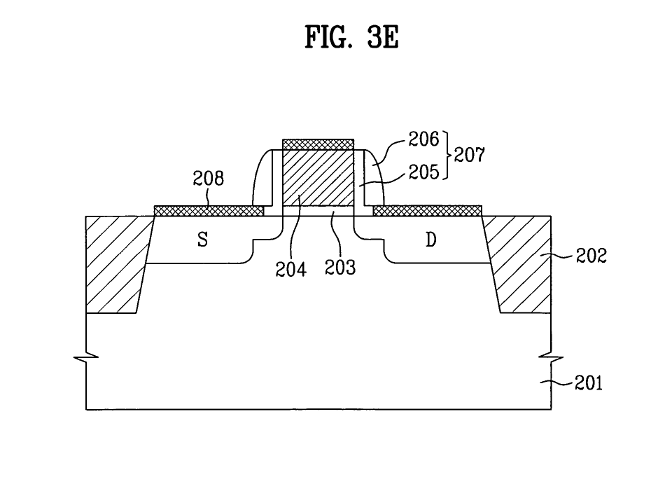

FIGS. 3A to 3E are cross-sectional diagrams for explaining a method of fabricating a semiconductor device according to the present invention.

Referring to FIG. 3A, a device isolation layer 202 is formed in a field area of a semiconductor substrate 201 by STI (shallow trench isolation) for electric insulation between active areas of the semiconductor substrate 201 that is p or n type.

An insulating layer for a gate insulating layer is then formed on the active areas of the semiconductor substrate 201. In doing so, an oxide layer is grown by thermal oxidation. And, a thickness of the oxide layer 203 depends on device characteristics.

A polysilicon layer for a gate electrode is deposited on the insulating layer by low pressure CVD (chemical vapor deposition).

The polysilicon layer and the insulating layer are selectively patterned to form a gate electrode 204 and a gate insulating layer 203 by photolithography.

Referring to FIG. 3B, LDD ion implantation is carried out on the substrate 201 to form lightly doped regions n⁻ in the active area of the semiconductor substrate 201. The lightly doped regions n⁻ oppose each other to be aligned with the gate electrode 204, respectively and are to be turned into LDD regions through annealing.

Referring to FIG. 3C, an insulating layer for forming a spacer 207 in FIG. 3D is formed on the semiconductor substrate 201. Namely, an oxide layer 205 and a nitride layer 206 are sequentially stacked on the semiconductor substrate 201 including the gate electrode 204. Preferably, the oxide layer 205 and the nitride layer 206 are formed 50˜100 Å and 100˜200 Å, respectively. Alternatively, the insulating layer for forming the spacer 207 can be formed of a triple layer consisting of an oxide layer/nitride layer/oxide layer as well as the double layer consisting of the oxide layer 205 and the nitride layer 206. Moreover, the oxide layer can be replaced by an oxynitride layer.

Subsequently, the nitride layer 206 and the oxide layer 205 are etched back by RIE (reactive ion etch) until the gate electrode 204 and the semiconductor substrate 201 are exposed. Hence, a spacer 207 consisting of the nitride layer 206 and the oxide layer 205 formed on a sidewall of the gate electrode 204.

Subsequently, source/drain ion implantation is carried out on the substrate 201 to form heavily doped regions n⁺ in the active area of the semiconductor substrate 201to be aligned with the spacer 207. The heavily doped regions n⁺ will be turned into source and drain regions through subsequent annealing.

Referring to FIG. 3D, a portion of the lower insulating layer 205, i.e., the oxide layer 205, configuring the spacer 207 is removed. Specifically, the oxide layer 205 is partially removed by isotropic wet etch. In ding so, diluted HF (DHF) can be used as an etchant of the isotropic wet etch. Preferably, 0.4-0.5 wt % HF is preferably used as the etchant. The etched portion of the oxide layer 205 is an outer edge of the oxide layer 205 contacting with the substrate 201. A width d of the etched oxide layer depends on a design rule of the semiconductor device and is preferably set to 30˜100 Å.

Thus, as the edge portion of the oxide layer 205 of the spacer 207 is removed to the prescribed width, the dislocation in the related art can be prevented.

Subsequently, the substrate 201 is annealed by rapid thermal processing at 600-1,000° C. or the like to form source and drain regions S and D by activating the heavily doped regions. In doing so, even if a surface and inside of the substrate corresponding to the heavily doped regions are in a irregular crystalline phase having point or line defect attributed to the dopants of the LDD and source/drain ion implantations, they are re-crystallized through the annealing. On re-crystallization, thermal stress was concentrated on the edge portion of the oxide layer of the spacer in the related art. Yet, in the present invention, since the edge portion of the oxide layer 205 was previously removed to the prescribed width, the thermal stress is concentrated on the edge portion of the spacer 207 on re-crystallization to prevent dislocation from occurring in the corresponding portion.

Referring to FIG. 3E, a high melting point metal layer is formed over the substrate 201 including the gate electrode 204 by sputtering or the like.

Subsequently, annealing is carried out on the substrate 201 to induce silicidation between silicon and metal on surfaces of the gate electrode 204 and the source/drain regions. Hence, a salicide (self-aligned silicide) layer 208 is formed on the surfaces of the gate electrode 204 and the source/drain regions of the semiconductor substrate 201. In doing so, the salicide layer 208 is formed of MoSi2, PdSi₂, PtSi₂, TaSi₂, and WSi₂ according to a species of the high melting point metal layer.

Meanwhile, the salicide layer 208 is provided in a manner that the high melting point metal layer on the substrate reacts with the substrate, i.e., silicon, to grow in a direction of the substrate 201. In doing so, a space having. been occupied by the removed portion of the oxide layer is filled up with the growing salicide layer 208, whereby electrical characteristics of the semiconductor device can be secured.

Accordingly, the present invention provides the following effects or advantages.

First of all, the edge portion of the oxide layer configuring the spacer is removed by wet etch to prevent the stress being concentrated on the lateral edge of the spacer 207. Therefore, the present invention prevents the dislocation.

Secondly, the space having been occupied by the removed portion of the oxide layer is filled up with the growing salicide layer, whereby the electrical characteristics of the semiconductor device can be uniformly sustained.

It will be apparent to those skilled in the art that various modifications and variations can be made in the present invention. Thus, it is intended that the present invention covers the modifications and variations of this invention provided they come within the scope of the appended claims and their equivalents.

1. A method of fabricating a semiconductor device, comprising the steps of:
forming a gate having a gate insulating layer underneath on a semiconductor substrate;
forming a pair of lightly doped regions in the substrate to be aligned with the gate;
forming, at least two insulating layers on the substrate including the gate;
forming a spacer on a sidewall of the gate by patterning the insulating layer;
removing an edge portion of a lower one of the at least two insulating layers to a prescribed width;
forming a pair of heavily doped regions in the substrate to be aligned with the spacer; and
forming a silicide layer on a surface of the gate electrode and exposed surfaces of the lightly and-heavily doped regions.

2. The method of claim 1, wherein the silicide layer fills up the removed portion.

3. The method of claim 1, wherein either a double layer of oxide/nitride or oxynitride/nitride or a triple layer of oxide/nitride/oxide is used as the at least two insulating layers.

4. The method of claim 1, wherein the prescribed width is 30˜100 Å.

5. The method of claim 1, wherein the edge portion is removed-by isotropic wet etch.

6. The method of claim 5, wherein 0.4-0.5 wt % diluted HF is used as an etchant for the isotropic etch.

7. A semiconductor device, comprising:
a gate having a gate insulating layer underneath on a semiconductor substrate;
a pair of lightly doped regions in the substrate to be aligned with the gate;
a spacer on a sidewall of the gate configured with at least two insulating layers wherein an edge portion of a lower one of the at least two insulating layers is removed to a prescribed width;
a pair of heavily doped regions in the substrate to be aligned with the spacer; and
a silicide layer on a surface of the gate electrode and exposed surfaces of the lightly and heavily doped regions.

8. The method of claim 7, wherein the silicide layer fills up the removed portion.

9. The method of claim7, wherein the prescribed width is 30˜100 Å.
